(19) United States
(12) Patent Application Publication
(10) Pub. No.: US 2016/0211432 A1
(43) Pub. Date: Jul. 21, 2016

(54) THERMOELECTRIC CONVERSION ELEMENT

(71) Applicant: FUJIFILM Corporation, Tokyo (JP)

(72) Inventor: Takeyoshi KANO, Ashigarakami-gun (JP)

(73) Assignee: FUJIFILM Corporation, Tokyo (JP)

(21) Appl. No.: 15/086,509

(22) Filed: Mar. 31, 2016

Related U.S. Application Data
(63) Continuation of application No. PCT/JP2014/076058, filed on Sep. 30, 2014.

(30) Foreign Application Priority Data
Oct. 1, 2013 (JP) 2013-206362

(51) Int. Cl. H01L 35/24

(52) U.S. Cl. CPC H01L 35/24

(57) ABSTRACT

A thermoelectric conversion element having, on a base material, a first electrode, a thermoelectric conversion layer, and a second electrode, in which a thermoelectric conversion layer is formed using a thermoelectric conversion material containing (a) a carbon nanotube and (b) a dispersing agent including a repeating unit represented by Formula (1A) and a repeating unit represented by Formula (1B):

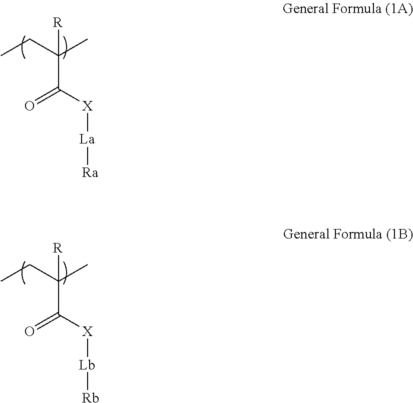

In Formulas (1A) and (1B), Ra represents an aromatic, alicyclic, alkyl, hydroxyl, thiol, amino, ammonium, or carboxyl group. Rb represents a monovalent group derived from a polyalkylene oxide, poly(meth)acrylate, polysiloxane, polyacrylonitrile, or polystyrene compound, a monovalent group obtained by combining the compounds, or an alkyl group having 5 or more carbon atoms. La and Lb represent a single bond or a divalent linking group. R represents a hydrogen atom or an alkyl group having 1 to 4 carbon atoms. X represents an oxygen atom or —NH—.

This application is a Continuation of PCT International Application No. PCT/JP2014/076058 filed on Sep. 30, 2014, which claims priority under 35 U.S.C. §119 (a) to Japanese Patent Application No. 2013-206362 filed on Oct. 1, 2013. Each of the above applications is hereby expressly incorporated by reference, in its entirety, into the present application.

### BACKGROUND OF THE INVENTION

1. Field of the Invention

The present invention relates to a thermoelectric conversion element.

2. Description of the Related Art

Thermoelectric conversion materials that can mutually convert heat energy and electric energy are used in thermoelectric power generating elements and in thermoelectric conversion elements such as Peltier devices. Thermoelectric power generation achieved by applying a thermoelectric conversion material or a thermoelectric conversion element enables direct conversion from heat energy to electric power, does not require any moving parts, and is used in wrist watches that are operated by body temperature, as well as in power supplies for remote areas and power supplies used in space.

As one of indexes that evaluate the thermoelectric conversion performance of a thermoelectric conversion element, there is a dimensionless figure of merit ZT (hereinafter, in some cases, simply referred to as the figure of merit ZT). The figure of merit ZT is represented by Equation (A) below, and important factors for the enhancement of the thermoelectric conversion performance are the increase in the thermoelectromotive force S per absolute temperature (hereinafter, in some cases, referred to as the thermoelectromotive force) and electrical conductivity σ and the reduction of thermal conductivity κ.

Figure of merit ZT=S²·σ·T/x (A)

In Equation (A), S (V/K): Thermoelectromotive force per absolute temperature (Seebeck coefficient)
σ (S/m): Electrical conductivity
κ (W/mK): Thermal conductivity
T (K): Absolute temperature

The thermoelectric conversion materials require favorable thermoelectric conversion performance, and thermoelectric conversion materials that have been mainly put into practical use at the moment are inorganic materials. However, inorganic materials need to undergo a complicated step to be processed into thermoelectric conversion elements, are expensive, and, in some cases, include harmful substances.

On the other hand, organic thermoelectric conversion elements can be manufactured at relatively low costs, and processes for forming films and the like are also easy, and thus, in recent years, active studies have been underway, and organic thermoelectric conversion materials and thermoelectric conversion elements manufactured using the organic thermoelectric conversion materials have been reported. In order to increase the figure of merit ZT of thermoelectric conversion, there is a demand for an organic material having a high Seebeck coefficient, high electric conductivity, and low thermal conductivity.

As organic materials having excellent electroconductive properties, carbon nanotubes are known. However, carbon nanotubes easily aggregate and have low dispersibility. Therefore, attempts are made to increase the dispersibility of carbon nanotubes. For example, JP2013-95821A proposes a composition containing an electroconductive polymer together with a carbon nanotube as a composition having excellent dispersibility of a carbon nanotube and proposes the use of the composition as a thermoelectric conversion material.

### SUMMARY OF THE INVENTION

An object of the present invention is to provide a thermoelectric conversion element manufactured using a thermoelectric conversion material which contains a carbon nanotube and a dispersing agent of the carbon nanotube, has favorable dispersibility of the nanocarbon material, and is excellent in terms of the electrical conductivity and the thermoelectromotive force.

The present inventors and the like carried out studies regarding compounds that improve the dispersibility of a carbon nanotube when being used together with the carbon nanotube. As a result, it was found that a particular compound having an anchoring group to a carbon nanotube and a steric repulsive group in the molecule is capable of favorably dispersing a carbon nanotube in a solvent. Furthermore, it was found that a composition containing the compound and a carbon nanotube exhibits excellent electrical conductivity and is useful as a thermoelectric conversion material. The invention has been completed on the basis of the above-described finding.

That is, according to the invention, the following means are provided:

<1> A thermoelectric conversion element having, on a base material, a first electrode, a thermoelectric conversion layer, and a second electrode, in which a thermoelectric conversion layer is formed using a thermoelectric conversion material containing (a) a carbon nanotube and (b) a dispersing agent including a repeating unit represented by General Formula (1A) below and a repeating unit represented by General Formula (1B) below:

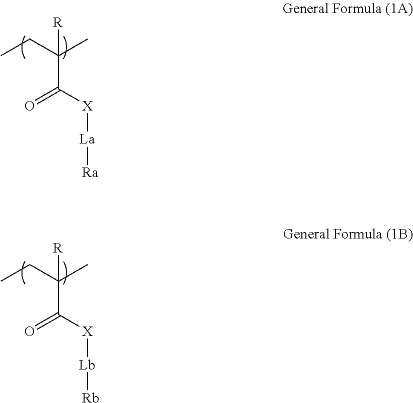

In General Formula (1A), Ra represents an aromatic group, an alicyclic group, an alkyl group, a hydroxyl group, a thiol group, an amino group, an ammonium group, or a carboxyl group. La represents a single bond or a divalent linking group. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R is identical to that in General Formula (1A). X represents an oxygen atom or —NH—.

<2> The thermoelectric conversion element according to <1>, in which, in General Formula (1A), X is —NH—.

<3> The thermoelectric conversion element according to <1> or <2>, in which, in General Formula (1A), X is —NH—, and Ra is an aromatic group.

<4> The thermoelectric conversion element according to <1>, in which, in General Formula (1A), X is an oxygen atom, and Ra is a hydroxyl group.

<5> The thermoelectric conversion element according to any one of <1> to <4>, in which, in General Formula (1B), Rb is a monovalent group derived from a poly(meth)acrylate compound.

<6> The thermoelectric conversion element according to any one of <I> to <5>, containing a solvent.

In the invention, a numerical value range described using “to” means a range including the values described before and after “to” as the lower limit value and the upper limit value.

In addition, in the invention, when an xxx group is mentioned as a substituent, the xxx group may have an arbitrary substituent. In addition, in case in which there are a plurality of groups indicated by the same reference signal, the groups may be identical to or different from each other.

Repeating structures illustrated by individual formulae do not have to be exactly the same repeating structures and may be different repeating structures as long as the repeating structures belong to the range represented by the formulae. For example, in case in which repeating structures have an alkyl group, repeating structures illustrated by individual formulae may be all repeating structures having a methyl group or may include repeating structures having a different alkyl group, for example, an ethyl group in addition to repeating structures having a methyl group.

The thermoelectric conversion element of the invention is formed of a thermoelectric conversion material which has favorable dispersibility of a carbon nanotube and has excellent electrical conductivity and exhibits excellent thermoelectric conversion performance.

The above-described and other characteristics and advantages of the invention will be more clarified by the following description with appropriate reference to the accompanying drawings.

### BRIEF DESCRIPTION OF THE DRAWINGS

FIG. 1 is a view schematically illustrating a section of an example of a thermoelectric conversion element of the present invention. The arrow in FIG. 1 indicates the direction of a temperature difference applied during the use of the element.

FIG. 2 is a view schematically illustrating a section of another example of the thermoelectric conversion element of the invention. The arrow in FIG. 2 indicates the direction of a temperature difference applied during the use of the element.

### DESCRIPTION OF THE PREFERRED EMBODIMENTS

A thermoelectric conversion material of the invention contains (a) a carbon nanotube and (b) a dispersing agent of the carbon nanotube as essential components and other components as necessary.

[(a) Carbon Nanotube]

As the carbon nanotube that is used in the invention (hereinafter, also referred to as CNT), there are a single-layer CNT that is a carbon film (graphene sheet) wound in a cylindrical shape, a bilayer CNT that is made of two graphene sheets wound in a concentric shape, and a multilayer CNT that is made of a plurality of graphene sheets wound in a concentric shape. In the invention, each of a single-layer CNT, a bilayer CNT, and a multilayer CNT may be used singly, or two or more kinds thereof may be used in combination. Particularly, a single-layer CNT and a bilayer CNT which have excellent properties in terms of electroconductive properties and semiconductor characteristics are preferably used, and a single-layer CNT is more preferably used.

In the case of a single-layer CNT, the symmetry of a spiral structure based on the orientation of hexagons of graphene in a graphene sheet is referred to as the axial chirality, and the two-dimensional lattice vector of a 6-membered ring from a standard point on graphene is referred to as the chiral vector. (n, m) obtained by indexing the chiral vector is referred to as the chiral index, and graphene is classified into metallic graphene and semiconductor graphene using this chiral index. Specifically, graphene having (n-m) that is a multiple of 3 exhibits metallic properties, and graphene having (n-m) that is not a multiple of 3 exhibits semiconductor properties.

A single-layer CNT that is used in the invention may be a semiconductor CNT or a metallic CNT, and both a semiconductor CNT and a metallic CNT may be jointly used. In addition, CNT may include a metal, and CNT including a molecule of a fullerene or the like (particularly, CNT including fullerene is referred to as a peapod) may also be used.

CNT can be manufactured using an arc discharge method, a chemical vapor deposition method (hereinafter, referred to as a CVD method), a laser application method, or the like. CNT that is used in the invention may be obtained using any method, but CNT obtained using an arc discharge method or a CVD method is preferred.

During the manufacturing of CNT, there are cases in which a fullerene or graphite and amorphous carbon are generated at the same time as byproducts. CNT may be purified in order to remove these byproducts. A method for purifying CNT is not particularly limited, and examples thereof include methods such as washing, centrifugal separation, filtration, oxidation, and chromatography. Additionally, an acid treatment using nitric acid, sulfuric acid, or the like and an ultrasonic treatment are also effective for removing impurities. It is more preferable to separate and remove impurities using a filter together with the above-described purification method from the viewpoint of improving the purity.

After purification, the obtained CNT may be used as it is. In addition, since CNT is generally generated in a string shape, CNT may be used after being cut into a desired length depending on the applications. CNT can be cut into a short fiber shape by means of an acid treatment using nitric acid, sulfuric acid, or the like, an ultrasonic treatment, or a frost shattering method. In addition, it is also preferable to separate impurities using a filter together with the above-described cutting method from the viewpoint of improving the purity.

In the invention, not only cut CNT but also CNT produced in a short fiber shape in advance can be used in the same manner. The above-described short fiber-shaped CNT is obtained in a shape in which CNT is aligned in a direction vertical to the substrate surface by, for example, forming a catalyst metal such as iron or cobalt on a substrate and growing CNT in a vapor phase on the surface by thermally decomposing a carbon compound at 700° C. to 900° C. using a CVD method. The short fiber-shaped CNT produced in the above-described manner can be pulled out from the substrate using a method such as peeling. In addition, the short fiber-shaped CNT can be obtained by supporting a catalyst metal on a porous support such as porous silicon or an anodized film of alumina and growing CNT on the surface thereof using a CVD method. It is also possible to produce an aligned short fiber-shaped CNT using a method in which a molecule such as iron phthalocyanine including a catalyst metal in the molecule is used as a raw material and CVD is performed in an argon/hydrogen gas flow, thereby producing CNT on the substrate. Furthermore, it is also possible to obtain a short fiber-shaped CNT aligned on a SiC crystal surface using an epitaxial growth method.

The average length of CNT is not particularly limited; however, from the viewpoint of easy manufacturing, film-forming properties, electroconductive properties, and the like, the average length thereof is preferably 0.01 μm to 1,000 μm and more preferably 0.1 μm to 100 μm. In addition, the average diameter of CNT is not particularly limited; however, from the viewpoint of durability, transparency, film-forming properties, electroconductive properties, and the like, the average diameter thereof is preferably 0.4 nm to 100 nm (more preferably 50 nm or smaller and still more preferably 15 nm or smaller).

The content of the carbon nanotube in the thermoelectric conversion material is preferably 5% by mass to 80% by mass, more preferably 5% by mass to 70% by mass, and particularly preferably 5% by mass to 50% by mass of the total solid content of the thermoelectric conversion material, that is, in a thermoelectric conversion layer from the viewpoint of the thermoelectric conversion performance.

Only one carbon nanotube may be used singly, or two or more kinds thereof may be used in combination.

[(b) Dispersing Agent of Carbon Nanotube]

The dispersing agent that is used in the invention is a polymer compound including a repeating unit represented by General Formula (1A) below and a repeating unit represented by General Formula (1B) below. The dispersing agent has an anchoring group to a carbon nanotube and a steric repulsive group.

Due to the above-described structure, the dispersing agent increases the dispersibility of a carbon nanotube in the thermoelectric conversion material and, furthermore, makes a thermoelectric conversion element comprising a thermoelectric conversion layer formed of the above-described material exhibit excellent thermoelectric conversion performance. The mechanism thereof is not yet clear but is assumed as described below.

That is, when the carbon nanotube and the dispersing agent of the invention are blended with a solvent or a resin, the dispersing agent is anchored to the carbon nanotube due to the action of the anchoring group. The carbon nanotube particles to which the dispersing agent is anchored are repulsed from each other due to the action of the steric repulsive group in the dispersing agent and thus become incapable of easily aggregating. As a result, the dispersibility of the carbon nanotube becomes favorable. When the dispersing agent is used together with the carbon nanotube in the thermoelectric conversion material, it is possible to obtain a thermoelectric conversion material having excellent dispersibility of the carbon nanotube. The above-described thermoelectric conversion material is extremely suitable for forming a thermoelectric conversion layer using a coating method.

In addition, in order to improve the thermoelectric conversion performance, in the thermoelectric conversion layer, it is desirable to allow charges to smoothly migrate and diffuse between the carbon nanotube particles. When the thermoelectric conversion layer is dried by removing the solvent or the like after the formation of the thermoelectric conversion layer by means of coating, the steric repulsive group in the dispersing agent shrinks, and thus the carbon nanotube particles easily come into contact with each other, and it becomes easy for a carrier path to be built between the carbon nanotube particles. Since the carrier path promotes the migration and diffusion of charges between the carbon nanotube particles, electroconductive properties and thermoelectromotive force improve. As a result, the thermoelectric conversion performance improves.

The dispersing agent of the invention is a copolymer including a repeating unit represented by General Formula (1A) below and a repeating unit represented by General Formula (1B) below:

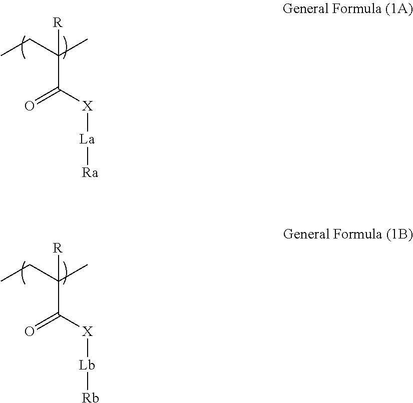

In General Formula (1A), Ra represents an aromatic group, an alicyclic group, an alkyl group, a hydroxyl group, a thiol group, an amino group, an ammonium group, or a carboxyl group. La represents a single bond or a divalent linking group. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R is identical to that in General Formula (1A). X represents an oxygen atom or —NH—.

Ra in General Formula (1A) corresponds to the anchoring group to the carbon nanotube. Ra is preferably an aromatic group or a hydroxyl group.

A ring constituting the aromatic group as Ra may be an aromatic hydrocarbon ring or an aromatic hetero ring, and examples of a heteroatom in the hetero ring include a nitrogen atom, a sulfur atom, an oxygen atom, and a selenium atom. In addition, the ring may be a single ring or a fused ring, and is preferably a 5-membered ring, a 6-membered ring, or a fused ring thereof and more preferably a 6-membered ring or a fused ring thereof. Specific examples thereof include a benzene ring, a naphthalene ring, an anthracene ring, a pyrene ring, a chrysene ring, a tetracene ring, a tetraphene ring, a triphenylene ring, an indole ring, an isoquinoline ring, a quinoline ring, a chromene ring, an acridine ring, a xanthene ring, a carbazole ring, a porphyrin ring, a chlorine ring, and a corrin ring. Ra is preferably an aromatic hydrocarbon ring, more preferably a benzene ring or a fused ring of a benzene ring, and still more preferably a benzene ring or a fused ring of 2 to 4 benzene rings that are fused together.

An alicyclic compound constituting the alicyclic group as Ra may include a heteroatom, and examples of the heteroatom include a nitrogen atom, a sulfur atom, an oxygen atom, and a selenium atom. In addition, the alicyclic compound may be a single ring or a fused ring, and is preferably a 5-membered ring, a 6-membered ring, or a fused ring thereof and more preferably a 6-membered ring or a fused ring thereof. In addition, the alicyclic compound may be a saturated ring or an unsaturated ring. Specific examples thereof include a cyclohexane ring, a cyclopropane ring, an adamantyl ring, and a tetrahydronaphthalene ring. The alicyclic compound is preferably a hydrocarbon ring which is a hydrocarbon ring of a 6-membered ring or a fused ring thereof.

The alkyl group as Ra may have any of a straight shape, a branched shape, and a cyclic shape and is preferably a straight alkyl group. The number of carbon atoms in the alkyl group is preferably 1 to 30 and more preferably 5 to 20.

Examples of the amino group as Ra include an alkylamino group and an arylamino group, and specific examples thereof include a dimethylamino group, a diethylamino group, a dibutylamino group, a dipropylamino group, a methylamino group, an ethylamino group, a butylamino group, a propylamino group, and an amino group. Among these, an alkylamino group is preferred. The number of carbon atoms in each of alkyl groups in the alkylamino group is preferably 1 to 7 and more preferably 1 to 4.

Examples of the ammonium group as Ra include an alkylammonium group and an arylammonium group. Specific examples thereof include a trimethylammonium group, a triethylammonium group, a tripropylammonium group, and a tributylammonium group. Among these, an alkylammonium group is preferred. The number of carbon atoms in each of alkyl groups in the alkylammonium group is preferably 1 to 7 and more preferably 1 to 4.

Examples of the thiol group as Ra include a thioalkyl group.

The respective groups as Ra may further have a substituent.

In General Formula (1A), examples of the divalent linking group as La include an alkylene group, —O—, —CO—, —COO—, —CONH—, —NH¹¹—, —N⁺R¹¹R¹²—, —S—, —S(═O)—, and divalent groups obtained by combining the above-described divalent linking groups. Here, each of R¹¹ and R¹² independently represents a hydrogen atom or an alkyl group, and the number of carbon atoms in the alkyl group is preferably 1 or 2. The alkylene group may have a substituent, and examples of the substituent include a hydroxyl group, a thiol group, an ether group, an ester group, and an amide group. The number of carbon atoms in the alkylene group is preferably 1 to 4 and more preferably 1 to 3.

La is preferably an alkylene group, a divalent group obtained by combining an alkylene group, —O—, and —CO—, or a divalent group obtained by combining an alkylene group, —N⁺R¹¹R¹²—, and —CO—. In case in which a plurality of groups are combined together, La more preferably bonds with X through the alkylene group and bonds with Rb through —CO—.

The alkyl group as R may have any of a straight shape, a branched shape, and a cyclic shape and is preferably a straight alkyl group. The alkyl group may be substituted, and a substituent is preferably a halogen atom, an oxygen atom, or a sulfur atom. The number of carbon atoms in the alkyl group is preferably 1 to 3 and more preferably 1 or 2.

R is preferably an alkyl group having 1 or 2 carbon atoms and more preferably a methyl group.

X is preferably —NH—. When X in General Formula (1A) is —NH—, the polarity of the dispersing agent increases. As a result, the interacting properties between the carbon nanotube and the dispersing agent become enhanced, the dispersibility of the carbon nanotube further improves, and the electrical conductivity also improves.

In General Formula (1A), in case in which X is —NH—, Ra is preferably an aromatic group. When X and Ra are combinations thereof in the dispersing agent, the dispersibility of CNT further improves.

In addition, in General Formula (1A), in case in which X is an oxygen atom, Ra is preferably a hydroxyl group. When X and Ra are combinations thereof in the dispersing agent, the film strength of the thermoelectric conversion layer improves. In the thermoelectric conversion element, an electrode is formed in contact with the thermoelectric conversion layer, and thus the film strength of the thermoelectric conversion layer is preferably higher since the scratch resistance becomes excellent. The reason why the film strength improves when X and R are combinations thereof is assumed that a hydrogen bond is generated in the film due to the hydroxyl group as Ra, and thus the strength of the film increases.

Specific examples of the repeating unit represented by General Formula (1A) (hereinafter, also referred to as repeating unit (1A)) will be illustrated below, but the invention is not limited thereto.

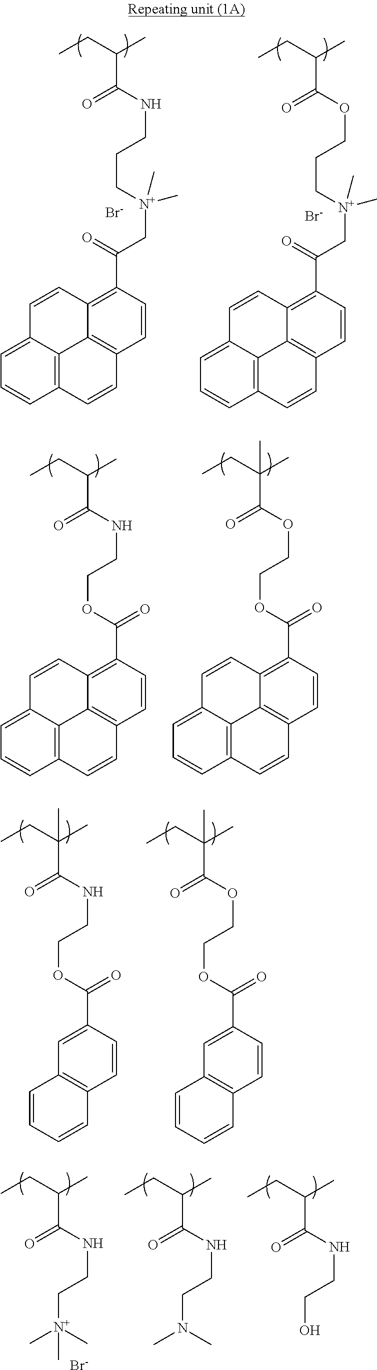

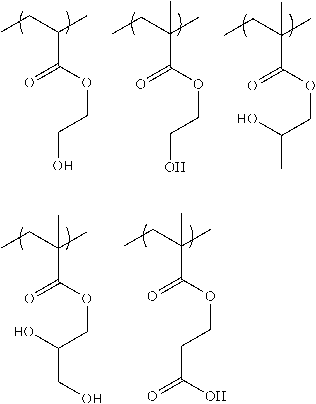

Rb in General Formula (1B) functions as the steric repulsive group.

The alkyl group as Rb may have any of a straight shape, a branched shape, and a cyclic shape and is preferably a straight alkyl group. The number of carbon atoms in the alkyl group is 5 or more, preferably 5 to 20, and more preferably 6 to 20. The alkyl group may have a substituent.

In case in which Rb is a monovalent group derived from a polyalkylene oxide compound, a poly(meth)acrylate compound, a polysiloxane compound, a polyacrylonitrile compound, or a polystyrene compound, Rb is preferably bonded with Lb at the terminal group of a polymer main chain thereof.

The repeating number of individual monomers constituting the polyalkylene oxide compound, the poly(meth)acrylate compound, the polysiloxane compound, the polyacrylonitrile compound, and the polystyrene compound is preferably 30 to 5,000 and more preferably 30 to 1,000.

The polyalkylene oxide compound, the poly(meth)acrylate compound, the polysiloxane compound, the polyacrylonitrile compound, or the polystyrene compound may have a substituent.

Specific examples of the polyalkylene oxide compound include polyethylene oxide, polypropylene oxide, and polybutylene oxide, and polyethylene oxide is preferred.

Specific examples of the poly(meth)acrylate compound include poly(methyl methacrylate), poly(isobutyl methacrylate), poly(ethyl methacrylate), poly(propyl methacrylate), poly(isopropyl methacrylate), poly(isobornyl methacrylate), poly(2-ethylhexyl methacrylate), poly(cyclohexyl methacrylate), poly(stearyl methacrylate), poly(tetrahydrofurfuryl methacrylate), poly(tridecyl methacrylate), poly(benzyl methacrylate), and poly(lauryl methacrylate), and poly(methyl methacrylate) and poly(isobutyl methacrylate) are preferred.

Specific examples of the polysiloxane compound include dimethylpolysiloxane and diethylpolysiloxane, and dimethylpolysiloxane is preferred.

Specific examples of the polyacrylonitrile compound include polyacrylonitrile.

Specific examples of the polystyrene compound include polystyrene and poly(4-methoxystyrene), and polystyrene is preferred.

Rb is preferably a monovalent group derived from the poly(meth)acrylate compound or the polystyrene compound and more preferably a monovalent group derived from the poly(meth)acrylate compound.

Examples of the divalent linking group as Lb include an alkylene group, —O—, —CO—, —COO—, —CONH—, —N⁺R¹¹R¹²—, —S—, —S(═O)—, and divalent groups obtained by combining the above-described divalent linking groups. Here, each of R¹¹ and R¹² independently represents a hydrogen atom or an alkyl group, and the number of carbon atoms in the alkyl group is preferably 1 or 2. The alkylene group may have a substituent, and examples of the substituent include a hydroxyl group, a halogen atom, an alkyl group, an alkoxy group, an amino group, an ammonium group, and an ester group. The number of carbon atoms in the alkylene group is preferably 1 to 7. In addition, the number of carbon atoms in Lb is preferably 1 to 20 and more preferably 1 to 10.

Lb is preferably a divalent group obtained by combining an alkylene group, —O—, —CO—, and —S—. In this case, Lb is more preferably bonded with X through the alkylene group and bonded with Rb through —S—.

R in General Formula (1B) is identical to that in General Formula (1A), and a preferred range thereof is also the same.

X in General Formula (1B) represents an oxygen atom or —NH— and is preferably an oxygen atom.

Specific examples of the repeating unit represented by General Formula (1B) (hereinafter, also referred to as repeating unit (1B)) will be illustrated below, but the invention is not limited thereto. Meanwhile, in the following specific examples, each of n and m represents an integer of 1 or greater:

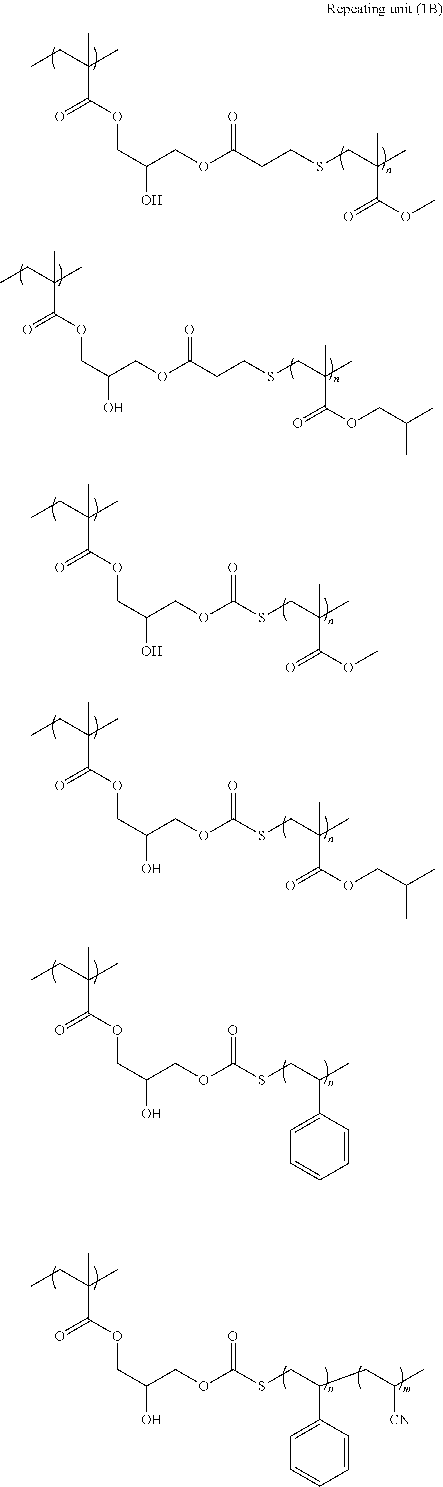

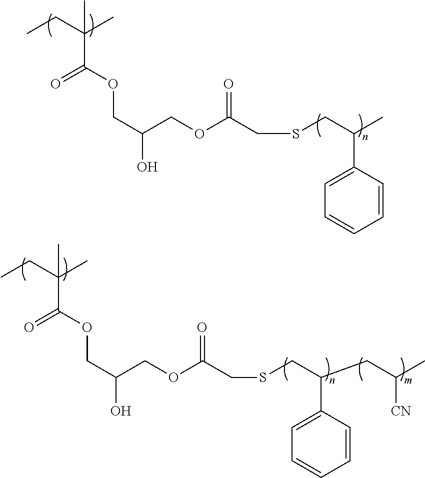

Specific examples of a combination of the repeating unit represented by General Formula (1A) and the repeating unit represented by General Formula (1B) will be illustrated below, but the invention is not limited thereto. Meanwhile, in the following specific examples, each of n and m represents an integer of 1 or greater:

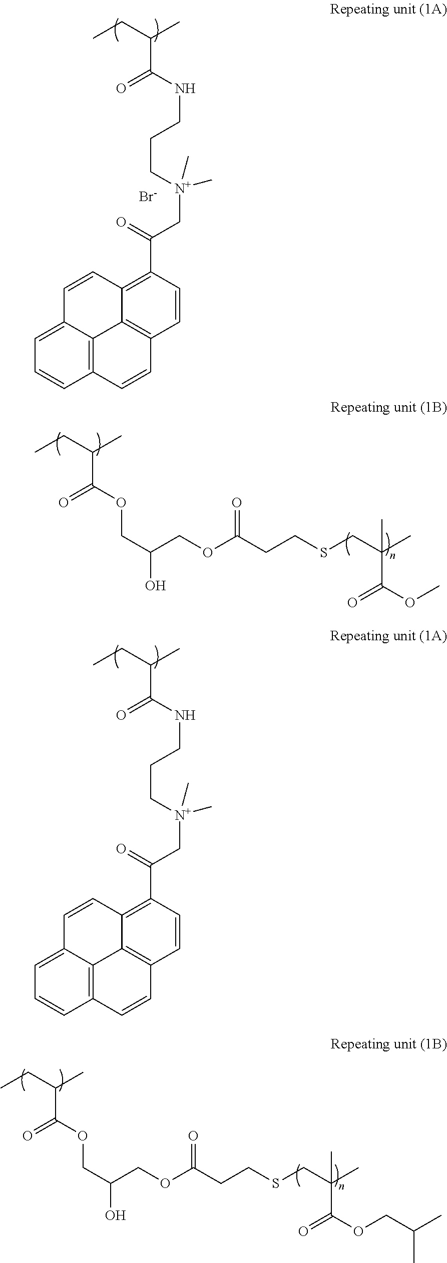

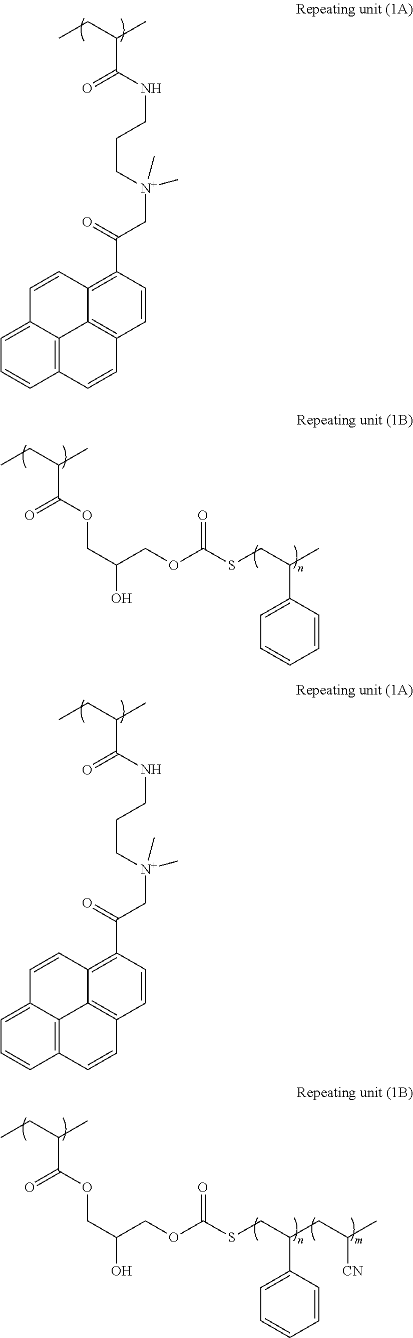

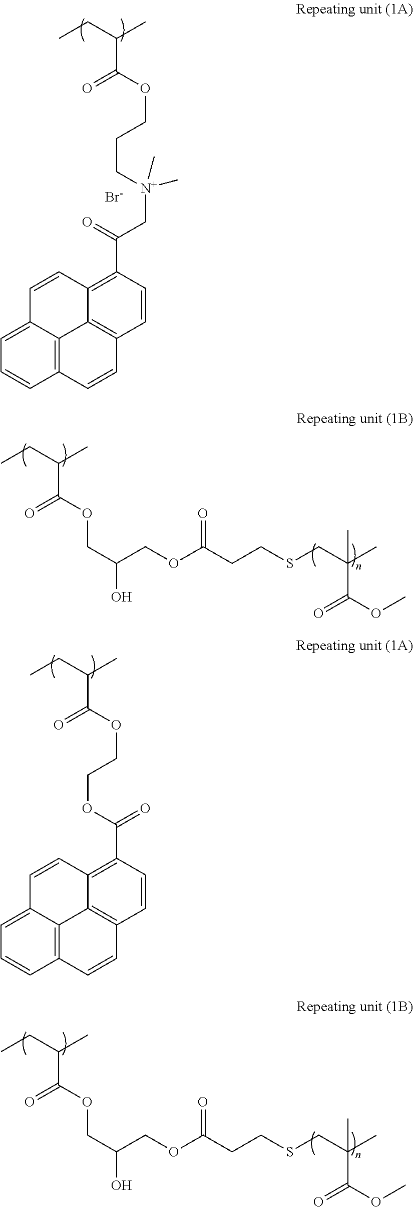

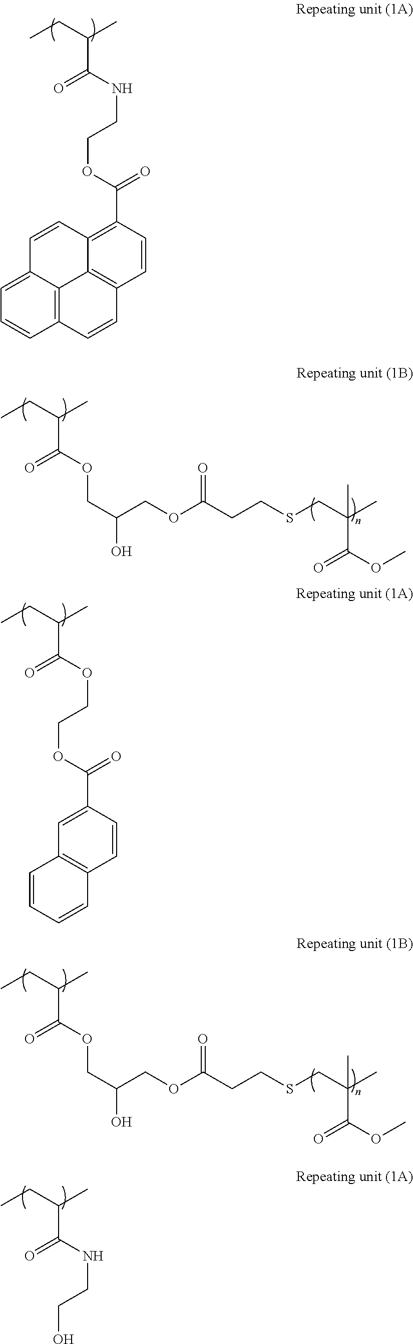

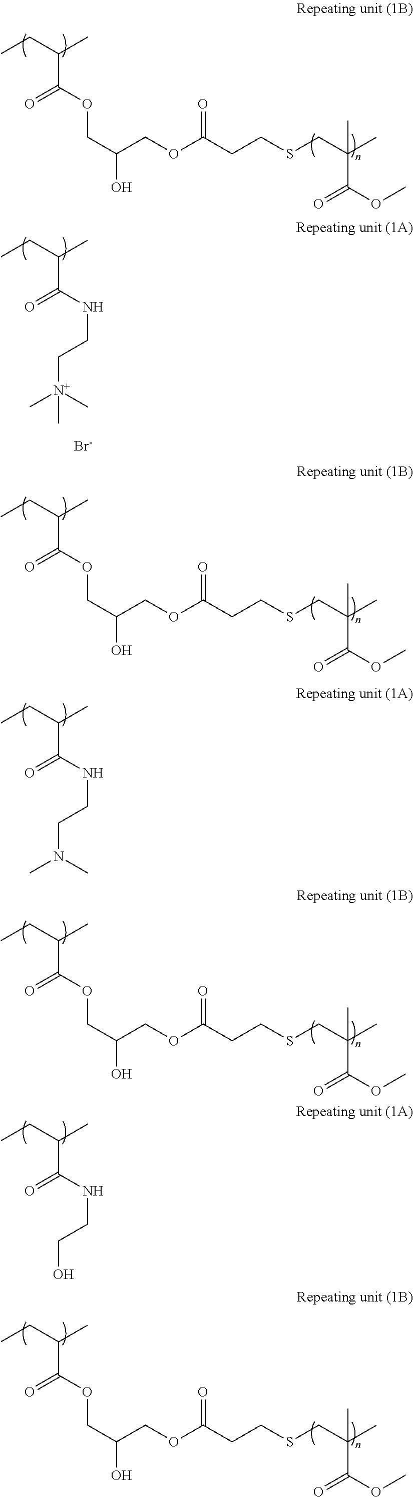

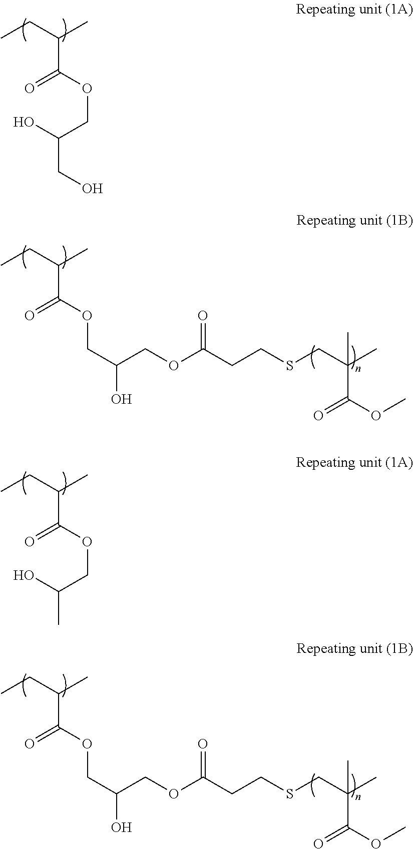

The dispersing agent of the invention may include a repeating unit other than the repeating units (1A) and (1B), and the repeating unit is preferably a copolymer consisting of the repeating units (1A) and (1B).

A copolymer including the repeating units (1A) and (1B) may be any one of a graft copolymer, a block copolymer, a random copolymer and an alternate copolymer. A graft copolymer is preferred since it is easy to uniformly dispose the steric repulsive group at a high density on the surface of a dispersion and to synthesize the graft copolymer. The above-described copolymer can be synthesized using a method in which a monomer and a macromonomer are copolymerized together, thereby obtaining a graft copolymer, a method in which a monomer and a monomer having a polymerization initiation site are copolymerized together and thus are polymerized from a polymer chain, a method in which a polymer reaction is performed between a polymer having a reactive group and another polymer, thereby synthesizing a graft copolymer, or the like. Among these, from the viewpoint of the introduction ratio of a graft chain and the easy control of the graft chain length and the like, the method in which a monomer and a macromonomer are copolymerized together, thereby obtaining a graft copolymer is preferred.

The graft copolymer preferably has a main chain formed by the copolymerization of the repeating unit (1A) and the repeating unit (1B) and has the steric repulsive group in the repeating unit (1B) as a side chain. In this case, the repeating unit (1B) site in the copolymer is preferably formed of a macromonomer. That is, the graft copolymer is preferably synthesized by copolymerizing a macromonomer capable of forming the repeating unit (1B) and a monomer capable of forming the repeating unit (1A).

Regarding the mole-based compositional ratio between the repeating units (1A) and (1B) in the copolymer including the repeating units (1A) and (1B), the repeating unit (1A):the repeating unit (1B) is preferably 20 to 90:80 to 10 and more preferably 40 to 80:60 to 20.

In addition, the weight-average molecular weight of the copolymer is preferably 1,000 to 800,000 and more preferably 10,000 to 300,000. Meanwhile, the weight-average molecular weight can be measured using gel permeation chromatography (GPC). For example, it is possible to calculate the weight-average molecular weight in terms of polystyrene using a high-speed GPC apparatus (for example, HLC-8220GPC (manufactured by Tosoh Corporation)) after dissolving a polymer compound in tetrahydrofuran (THF).

The percentage content of the dispersing agent in the thermoelectric conversion material is preferably 5 parts by mass to 100 parts by mass and more preferably 10 parts by mass to 80 parts by mass, relative to 100 parts by mass of the carbon nanotube, from the viewpoint of the thermoelectric conversion performance.

In the thermoelectric conversion material of the invention, the dispersing agent may be used singly, or two or more kinds thereof may be used in combination.

[(c) Dispersion Medium]

The thermoelectric conversion material of the invention preferably contains a dispersion medium.

The dispersion medium may be any dispersion medium capable of dispersing the carbon nanotube, and water, an organic solvent, and a solvent mixture thereof can be used. The dispersion medium is preferably an organic solvent, and aliphatic halogen-based solvents such as an alcohol and chloroform, aprotic polar solvents such as N,N-dimethylformamide (DMF), N-methylpyrrolidone (NMP), and dimethyl sulfoxide (DMSO), aromatic solvents such as chlorobenzene, dichlorobenzene, benzene, toluene, xylene, mesitylene, tetralin, tetramethyl benzene, and pyridine, ketone-based solvents such as cyclohexanone, acetone, and methyl ethyl ketone, ether-based solvents such as diethyl ether, tetrahydrofuran (THF), t-butyl methyl ether, dimethoxyethane, and diglyme, and the like are preferred, and aliphatic halogen-based solvents such as chloroform, aprotic polar solvents such as DMF and NMP, aromatic solvents such as dichlorobenzene, xylene, tetralin, and tetramethyl benzene, ether-based solvents such as THF, and the like are more preferred.

In the thermoelectric conversion material of the invention, the dispersion medium can be used singly, or two or more kinds of dispersion media can be used in combination.

In addition, the dispersion medium is preferably degassed in advance. The dissolved oxygen level in the dispersion medium is preferably set to 10 ppm or less. Examples of a degassing method include a method in which ultrasonic waves are radiated at a reduced pressure and a method in which an inert gas such as argon is bubbled.

Furthermore, the dispersion medium is preferably dehydrated in advance. The amount of moisture in the dispersion medium is preferably set to 1,000 ppm or less and more preferably set to 100 ppm or less. As a method for dehydrating the dispersion medium, it is possible to use a well-known method such as the use of a molecular sieve or distillation.

The amount of the dispersion medium in the thermoelectric conversion material is preferably 25% by mass to 99.99% by mass, more preferably 30% by mass to 99.95% by mass, and still more preferably 30% by mass to 99.9% by mass, relative to the total amount of the thermoelectric conversion material.

[Other Components]

The thermoelectric conversion material of the invention may contain other components in addition to the carbon nanotube, the dispersing agent, and the dispersion medium.

Examples of other components include polymer compounds other than the dispersing agent (hereinafter, other polymer compounds), an oxidation inhibitor, a light-fast stabilizer, a heat-resistant stabilizer, and a plasticizer.

Examples of the other polymer compounds include conjugated polymers and non-conjugated polymers.

Examples of the oxidation inhibitor include IRGANOX 1010 (trade name, manufactured by Ciba-Geigy Japan Limited), SUMILIZER GA-80 (trade name, manufactured by Sumitomo Chemical Co., Ltd.), SUMILIZER GS (trade name, manufactured by Sumitomo Chemical Co., Ltd.), and SUMILIZER GM (trade name, manufactured by Sumitomo Chemical Co., Ltd.).

Examples of the light-fast stabilizer include TINUVIN 234 (trade name, manufactured by BASF), CHIMASSORB 81 (trade name, manufactured by BASF), and CYASORB UV-3853 (trade name, manufactured by Sun Chemical Company LTD.).

Examples of the heat-resistant stabilizer include IRGANOX 1726 (trade name, manufactured by BASF). Examples of the plasticizer include ADEKACIZER RS (trade name, manufactured by Adeka Corp.).

The percentage content of the other components is preferably 5% by mass or less and more preferably 0% by mass to 2% by mass, relative to the total solid content of the thermoelectric conversion material.

[Preparation of Thermoelectric Conversion Material]

The thermoelectric conversion material of the invention can be prepared by mixing the respective components described above. Preferably, the thermoelectric conversion material is prepared by mixing the carbon nanotube, the dispersing agent, and the other components as desired into the dispersion medium, and dispersing the carbon nanotube.

There are no particular limitations on the method for preparing the thermoelectric conversion material, and the method can be carried out at a normal temperature and a normal pressure using a conventional mixing apparatus or the like. For example, the thermoelectric conversion material may be produced by stirring, shaking or kneading various components in a solvent, and thereby dissolving or dispersing the components. In order to promote dissolution or dispersion, an ultrasonication treatment may be carried out.

Furthermore, the dispersibility of the carbon nanotube can be increased by heating the solvent to a temperature that is higher than or equal to room temperature and lower than or equal to the boiling point in the dispersing step, by extending the dispersion time, or by increasing the application intensity of stirring, percolation, kneading, ultrasonication or the like.

[Thermoelectric Conversion Element]

A thermoelectric conversion element of the invention has, on a base material, a first electrode, a thermoelectric conversion layer, and a second electrode, and the thermoelectric conversion layer is formed using the thermoelectric conversion material of the invention.

Since the thermoelectric conversion element functions by maintaining a temperature difference in the thickness direction or the surface direction of the thermoelectric conversion layer, the thermoelectric conversion layer needs to have a certain degree of thickness. Therefore, in case in which the thermoelectric conversion layer is formed using a coating method, the thermoelectric conversion material to be applied needs to have favorable coatability and film-forming properties. The thermoelectric conversion material of the invention has favorable dispersibility of the carbon nanotube and is excellent in terms of coatability or film-forming properties, and is thus suitable for being molded and processed into the thermoelectric conversion layer.

As long as the thermoelectric conversion element of the invention has, on a base material, a first electrode, a thermoelectric conversion layer, and a second electrode, and at least one surface of the thermoelectric conversion layer is disposed so as to be in contact with the first electrode and the second electrode, there are no particular limitations on other constitutions such as the positional relationship between the first electrode, the second electrode, and the thermoelectric conversion layer. For example, the thermoelectric conversion element may have an embodiment in which the thermoelectric conversion layer is sandwiched between the first electrode and the second electrode, that is, an embodiment in which the first electrode, the thermoelectric conversion layer, and the second electrode are provided on the base material in this order. In addition, the thermoelectric conversion element may have an embodiment in which the first electrode and the second electrode are disposed so as to be in contact with one surface of the thermoelectric conversion layer, that is, an embodiment in which the first electrode and the second electrode are formed apart from each other on the same base material and the thermoelectric conversion layer is laminated on both electrodes.

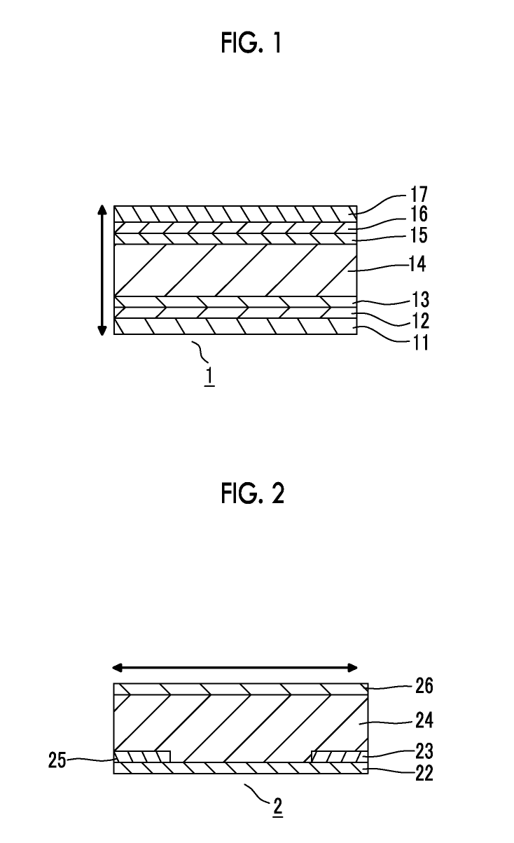

Examples of the structure of the thermoelectric conversion element of the invention include the structures of the element illustrated in FIGS. 1 and 2. In FIGS. 1 and 2, the arrows indicate the directions of temperature differences during the use of the thermoelectric conversion element.

A thermoelectric conversion element 1 illustrated in FIG. 1 comprises a pair of electrodes including a first electrode 13 and a second electrode 15 and a thermoelectric conversion layer 14 formed of the thermoelectric conversion material of the invention between the electrodes 13 and 15 on a first base material 12. A second base material 16 is disposed on the other surface of the second electrode 15, and metal plates 11 and 17 are disposed opposite to each other on the outside of the first base material 12 and the second base material 16.

In a thermoelectric conversion element 2 illustrated in FIG. 2, a first electrode 23 and a second electrode 25 are disposed on a first base material 22, and a thermoelectric conversion layer 24 formed of the thermoelectric conversion material of the invention is provided thereon.

From the viewpoint of protecting the thermoelectric conversion layer, the surface of the thermoelectric conversion layer is preferably covered with the electrode or the base material. For example, as illustrated in FIG. 1, it is preferable that one surface of the thermoelectric conversion layer 14 is covered with the first base material 12 through the first electrode 13 and the other surface is covered with the second base material 16 through the second electrode 15. In this case, the second electrode 15 may be exposed to air as an outermost surface without providing the second base material 16 on the outside of the second electrode 15. In addition, as illustrated in FIG. 2, it is preferable that one surface of the thermoelectric conversion layer 24 is covered with the first electrode 23, the second electrode 25, and the first base material 22 and the other surface is also covered with a second base material 26.

In addition, on the surface (a surface that is pressure-bonded to the thermoelectric conversion layer) of a base material that is used for the thermoelectric conversion element, the electrodes are preferably formed in advance. It is preferable that the base material or the electrodes and the thermoelectric conversion layer are pressure-bonded to each other by heating the members to approximately 100° C. to 200° C. from the viewpoint of improving the adhesiveness.

As the base material (the first base material 12 and the second base material 16 in the thermoelectric conversion element 1) in the thermoelectric conversion element of the invention, it is possible to use a base material such as glass, transparent ceramic, metal, or a plastic film. In the thermoelectric conversion element of the invention, the base material preferably has flexibility and, specifically, preferably has a flexibility at which the endurance number of cycles in a bend test (MIT) by the measurement method regulated by ASTM D2176 is 10,000 cycles or more. The base material having the above-described flexibility is preferably a plastic film, and specific examples thereof include polyester films such as films of polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester film of bisphenol A with iso- and terephthalic acid; polycycloolefine films such as a ZEONOR film (trade name, manufactured by Zeon Corp.), an ARTON film (trade name, manufactured by JSR Corp.), and SUMILITE FS1700 (trade name, manufactured by Sumitomo Bakelite Co., Ltd.); polyimide films such as KAPTON (trade name, manufactured by Du Pont-Toray Co., Ltd.), APICAL (trade name, manufactured by Kaneka Corp.), UPILEX (trade name, manufactured by Ube Industries, Ltd.), and POMIRAN (trade name, manufactured by Arakawa Chemical Industries, Ltd.); polycarbonate films such as PURE-ACE (trade name, manufactured by TEIJIN LIMITED.) and ELMECH (trade name, manufactured by Kaneka Corp.); polyether ether ketone films such as SUMILITE FS1100 (trade name, manufactured by Sumitomo Bakelite Co., Ltd.); and polyphenyl sulfide films such as TORELINA (trade name, manufactured by Toray Industries, Inc.). From the viewpoints of easy availability, heat resistance (preferably at 100° C. or higher), economic efficiency, and effectiveness, commercially available polyethylene terephthalate, polyethylene naphthalate, a variety of polyimides or polycarbonate films, and the like are preferred.

The base material is preferably used after being provided with the electrode on the surface that is pressure-bonded to the thermoelectric conversion layer. As an electrode material forming the first electrode and the second electrode that are provided on the base material, it is possible to use a transparent electrode of ITO, ZnO, or the like; a metal electrode of silver, copper, gold, aluminum, or the like; a carbon material such as CNT or graphene; an organic material such as PEDOT/PSS; an electroconductive paste obtained by dispersing electroconductive fine particles of silver, carbon, or the like; and an electroconductive paste containing a metal nanowire of silver, copper, aluminum, or the like. Among these, a metal electrode of silver, copper, gold, aluminum, or the like or an electroconductive paste containing the above-described metal is preferred.

From the viewpoint of handling properties, durability, and the like, the thickness of the base material is preferably 30 μm to 3,000 μm, more preferably 50 μm to 1,000 μm, still more preferably 100 μm to 1,000 μm, and particularly preferably 200 μm to 800 μm. When the thickness of the base material is set in this range, the thermal conductivity does not decrease, and the thermoelectric conversion layer is not easily damaged due to an external impact.

The layer thickness of the thermoelectric conversion layer is preferably 0.1 μm to 1,000 μm and more preferably 0.5 μm to 100 When the film thickness is set in this range, it is easy to apply a temperature difference, and an increase in the resistance in the film can be prevented.

Generally, the thermoelectric conversion element can be simply manufactured compared with a photoelectric conversion element such as an organic thin film solar cell element. Particularly, when the thermoelectric conversion material of the invention is used, compared with an organic thin film solar cell element, it is not necessary to consider the light absorption efficiency, and thus it is possible to increase the thickness by approximately 100 times to 1,000 times, and the chemical stability with respect to oxygen or moisture in the air improves.

A method for forming the thermoelectric conversion layer is not particularly limited, and, for example, a known coating method such as spin coating, extrusion die coating, blade coating, bar coating, screen printing, stencil printing, roll coating, curtain coating, spray coating, or dip coating can be used. Among these, screen printing is particularly preferred since the adhesiveness of the thermoelectric conversion layer to the electrode is excellent.

After the formation of the film, it is preferable to carry out a drying step as necessary, thereby removing the solvent. For example, the solvent can be volatilized and dried by heating and drying the thermoelectric conversion material or blowing hot air.

The thermoelectric conversion element of the invention exhibits excellent thermoelectric conversion performance and can be preferably used as a power generating element for a thermoelectric power generating component. Specific examples of the power generating element include electric power generators such as a hot spring electrical heat generator, a solar heat power generator, and a waste heat power generator, a power supply for a wrist watch, a semiconductor-driven power supply, and a power supply for a (small-sized) sensor.

### EXAMPLES

Hereinafter, the present invention will be explained in more detail by way of Examples, but the invention is not intended to be limited to these.

Dispersing agents used in the examples will be described below. In the following chemical formulae, the numbers of individual repeating units represent mole %. The molecular weights of these dispersing agents are as described below. The weight-average molecular weight was measured using gel permeation chromatography (GPC).

Dispersing agent 1: Weight-average molecular weight=32,000

Dispersing agent 2: Weight-average molecular weight=25,000

Dispersing agent 3: Weight-average molecular weight=19,000

Dispersing agent 4: Weight-average molecular weight=25,000

Dispersing agent 5: Weight-average molecular weight=52,000

Dispersing agent 6: Weight-average molecular weight=22,000

Dispersing agent 7: Weight-average molecular weight=85,000

In addition, as a dispersing agent c1 for comparison, a polymethyl methacrylate resin (PMMA, the weight-average molecular weight: 28,000) was used.

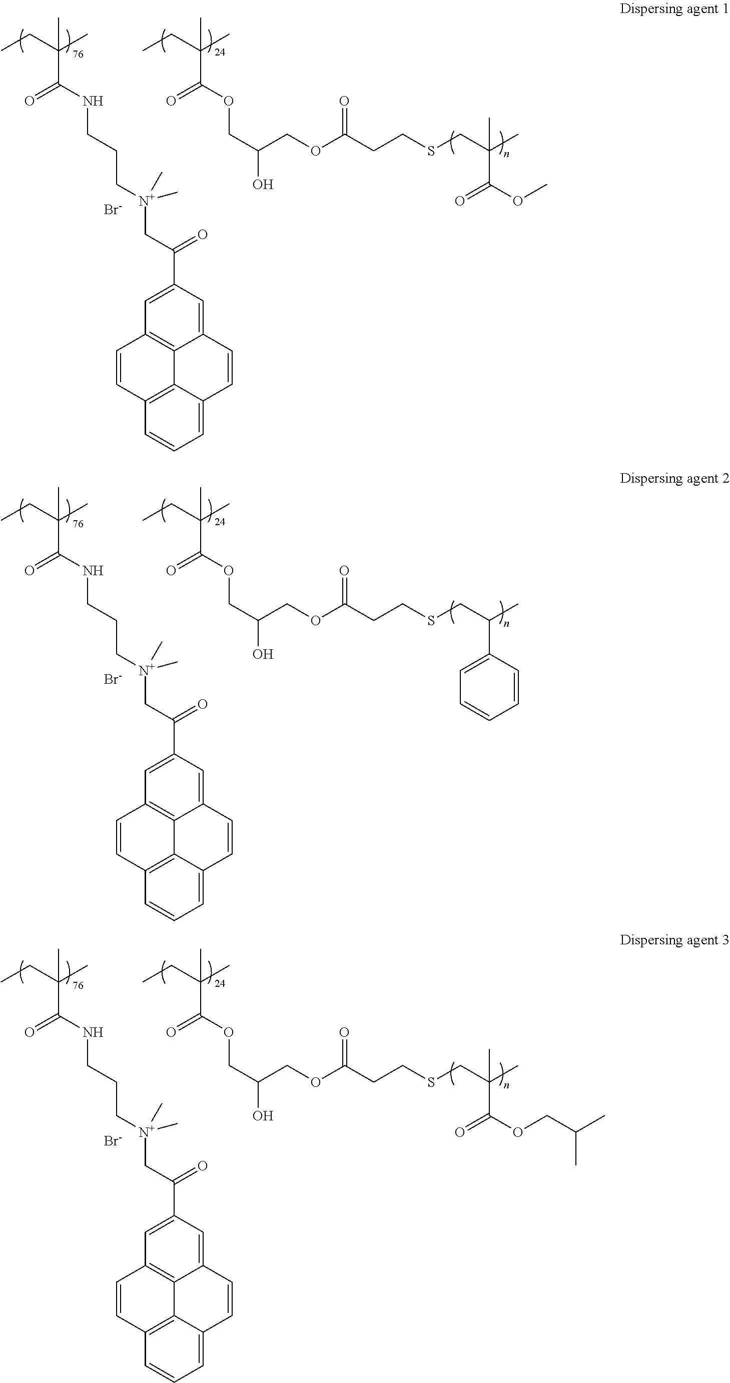

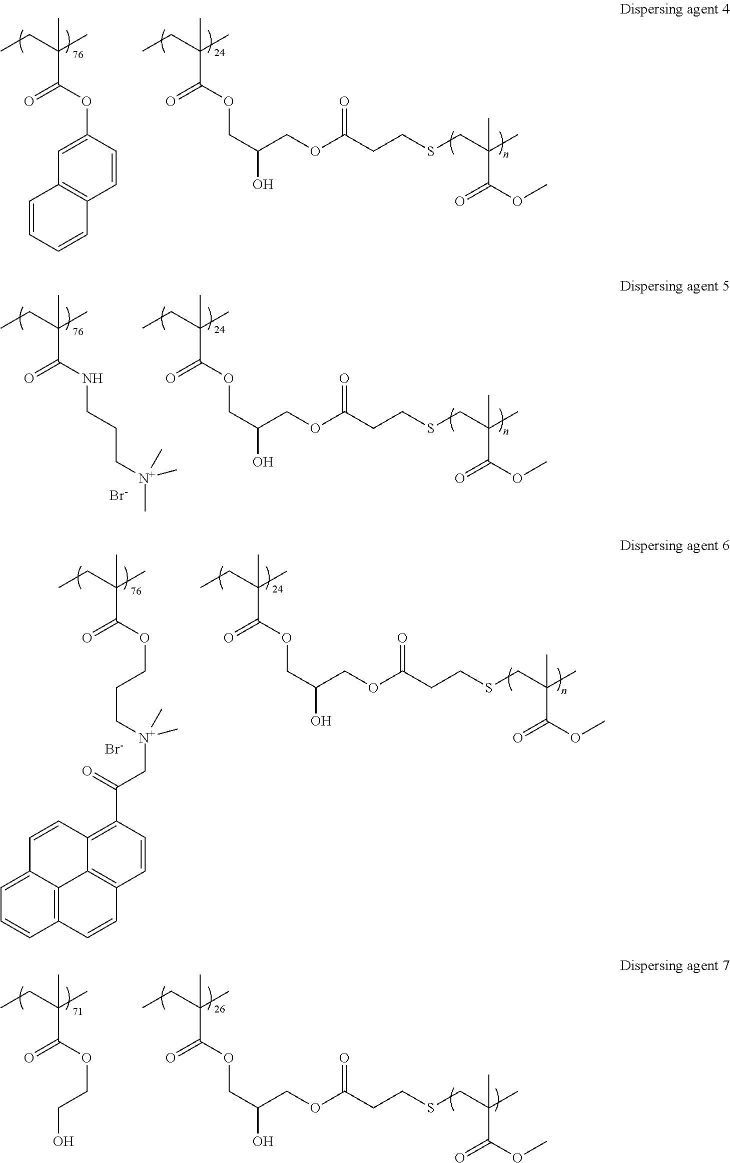

Synthesis of Macromonomer of Polymethyl Methacrylate (PMMA)

100 g of methyl methacrylate and 0.35 g of thiopropionic acid were injected into a 250 mL three-neck flask and were heated to 80° C. After the heating, 17 mg of azobisisobutyronitrile (AIBN, manufactured by Wako Pure Chemical Industries, Ltd.) was injected thereinto and was reacted for 40 minutes, and then, repeatedly, 17 mg of AIBN (manufactured by Wako Pure Chemical Industries, Ltd.) was injected thereinto and was reacted for 40 minutes twice. After that, 10 g of tetrahydrofuran was injected thereinto, thereby ending the reaction. The reaction liquid was precipitated again, thereby obtaining 60 g of an intermediate body A.

15 g of the obtained intermediate body A, 30 g of xylene, 0.28 g of glycidyl methacrylate, 0.01 g of hydroquinone, and 0.01 g of dimethyl laurylamine were injected into a 250 mL three-neck flask and were reacted for five hours under reflux conditions. After that, the reaction liquid was precipitated again, thereby obtaining 10 g of a macromonomer of polymethyl methacrylate (PMMA).

Synthesis of Macromonomer of Polystyrene

110 g of styrene and 0.35 g of thiopropionic acid were injected into a 250 mL three-neck flask and were heated at 80° C. After the heating, 17 mg of AIBN (manufactured by Wako Pure Chemical Industries, Ltd.) was injected thereinto and was reacted for 40 minutes, and then, repeatedly, 17 mg of AIBN (manufactured by Wako Pure Chemical Industries, Ltd.) was injected thereinto and was reacted for 40 minutes twice. After that, 10 g of tetrahydrofuran was injected thereinto, thereby ending the reaction. After that, the reaction liquid was precipitated again, thereby obtaining 65 g of an intermediate body B.

15 g of the obtained intermediate body B, 30 g of xylene, 0.28 g of glycidyl methacrylate, 0.01 g of hydroquinone, and 0.01 g of dimethyl laurylamine were injected into a 250 mL three-neck flask and were reacted for five hours under reflux conditions. After that, the reaction liquid was precipitated again, thereby obtaining 13 g of a macromonomer of polystyrene.

Synthesis of Macromonomer of Polyisobutyl Methacrylate

115 g of isobutyl methacrylate and 0.35 g of thiopropionic acid were injected into a 250 mL three-neck flask and were heated at 80° C. After the heating, 17 mg of AIBN (manufactured by Wako Pure Chemical Industries, Ltd.) was injected thereinto and was reacted for 40 minutes, and then, repeatedly, 17 mg of AIBN (manufactured by Wako Pure Chemical Industries, Ltd.) was injected thereinto and was reacted for 40 minutes twice. After that, 10 g of tetrahydrofuran was injected thereinto, thereby ending the reaction. After that, the reaction liquid was precipitated again, thereby obtaining 70 g of an intermediate body C.

15 g of the obtained intermediate body C, 30 g of xylene, 0.28 g of glycidyl methacrylate, 0.01 g of hydroquinone, and 0.01 g of dimethyl laurylamine were injected into a 250 mL three-neck flask and were reacted for five hours under reflux conditions. After that, the reaction liquid was precipitated again, thereby obtaining 15 g of a macromonomer of polyisobutyl methacrylate.

### Synthesis Example 1

### Synthesis of Dispersing Agent 1

5 g of 1-bromoacetylpyrene, 2.7 g of dimethylaminopropyl acrylamide, and 50 mL of tetrahydrofuran were injected into a 300 mL three-neck flask and were reacted at room temperature for three hours. After the reaction, the precipitate of the reaction liquid was filtered, thereby obtaining 6 g of a target monomer 1.

1 g of the monomer 1 obtained above, 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 1 (dispersing agent 1).

### Synthesis Example 2

### Synthesis of Dispersing Agent 2

1 g of the monomer 1 synthesized in Synthesis Example 1, 4 g of the macromonomer of polystyrene synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 2 (dispersing agent 2).

### Synthesis Example 3

### Synthesis of Dispersing Agent 3

1 g of the monomer 1 synthesized in Synthesis Example 1, 4 g of the macromonomer of polyisobutyl methacrylate synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 3 (dispersing agent 3).

### Synthesis Example 4

### Synthesis of Dispersing Agent 4

0.5 g of naphthyl methacrylate, 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 4 (dispersing agent 4).

### Synthesis Example 5

### Synthesis of Dispersing Agent 5

0.6 g of 3-(trimethylammonium bromide), 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 5 (dispersing agent 5).

### Synthesis Example 6

### Synthesis of Dispersing Agent 6

5 g of 1-bromoacetylpyrene, 2.7 g of dimethylaminopropyl methacrylate, and 50 mL of tetrahydrofuran were injected into a 300 mL three-neck flask and were reacted at room temperature for three hours. After the reaction, the precipitate of the reaction liquid was filtered, thereby obtaining 5 g of a target monomer 6.

1 g of the monomer 6 obtained above, 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 6 (dispersing agent 6).

### Synthesis Example 7

### Synthesis of Dispersing Agent 7

0.27 g of 2-hydroxyethyl methacrylate, 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 7 (dispersing agent 7).

### Example 1

### Thermoelectric Conversion Element 101

5 mg of the dispersing agent 1 and 5 mg of a single-layer CNT (manufactured by KH Chemicals) were added to 10 ml of ortho-dichlorobenzene and were dispersed using an ultrasonic homogenizer for 20 minutes, thereby preparing a dispersion liquid 101.

As a base material, a glass substrate having a thickness of 1.1 mm and a size of 40 mm×50 mm was used. After this base material was ultrasonic-washed in acetone, a UV-ozone treatment was carried out for 10 minutes. After that, gold pieces having a size of 30 mm×5 mm and a thickness of 10 nm were respectively formed on both end part sides of the base material as a first electrode and a second electrode.

A TEFLON (registered trademark) frame was attached onto the base material on which the electrodes were formed, the prepared dispersion liquid 101 was poured into the frame and was dried on a hot plate at 60° C. for one hour, the frame was removed after the drying, and a thermoelectric conversion layer having a thickness of approximately 1.1 μm was formed, thereby producing a thermoelectric conversion element 101 having the constitution illustrated in FIG. 1.

Dispersion liquids 102 to 106 and c101 and thermoelectric conversion elements 102 to 106 and c101 were produced in the same manner as the dispersion liquid 101 and the thermoelectric conversion element 101, except that the dispersing agents shown in Table 1 were used instead of the dispersing agent 1.

The temporal change of the dispersibility of CNT in the dispersion liquid and the electrical conductivity and the thermoelectromotive force of the thermoelectric conversion element were evaluated using the following methods.

[Temporal Change of Dispersibility]

The dispersion liquid was stored for two days, and the sedimentation property of CNT was evaluated using the following standards.

A: The sedimentation of CNT was not visually confirmed after centrifugal separation was carried out at 500 rpm for five minutes.

B: The sedimentation of CNT was not visually confirmed.

C: The sedimentation of CNT was visually confirmed.

[Thermoelectromotive Force and Electrical Conductivity]

The first electrode of each thermoelectric conversion element was disposed on a hot plate maintained at a constant temperature, and a Peltier device for temperature control was disposed on the second electrode.

While the temperature of the hot plate was maintained constant (100° C.), the temperature of the Peltier device was decreased, and thereby a temperature difference (in the range of more than 0 K but no more than 4 K) was applied between the two electrodes.

At this time, the thermoelectromotive force (μV) generated between the two electrodes was divided by the particular temperature difference (K) generated between the two electrodes, and thereby the thermoelectromotive force S per unit temperature difference (μV/K) was calculated. In addition, simultaneously, the electrical conductivity (S/cm) was calculated by measuring an electrical current generated between the two electrodes.

TABLE 1

| | | | Electrical | | |
|---|---|---|---|---|---|
| Thermoelectric | | Temporal change of | conductivity | Thermoelectromotive force S | |
| conversion element | Dispersing agent | dispersibility | (S/cm) | (μV/K) | Note |
| 101 | 1 | A | 320 | 35 | Present |
| | | | | | Invention |
| 102 | 2 | B | 250 | 34 | Present |
| | | | | | Invention |
| 103 | 3 | A | 300 | 30 | Present |
| | | | | | Invention |
| 104 | 4 | B | 230 | 32 | Present |
| | | | | | Invention |
| 105 | 5 | B | 250 | 31 | Present |
| | | | | | Invention |
| 106 | 6 | B | 290 | 30 | Present |
| | | | | | Invention |
| c101 | c1 | C | 120 | 28 | Comparative |
| | | | | | example |

As is clear from Table 1, the thermoelectric conversion materials manufactured using the dispersing agent of the invention maintained the dispersibility of CNT over time. In addition, the thermoelectric conversion elements manufactured using the thermoelectric conversion materials exhibited a high electrical conductivity and a high thermoelectromotive force and were excellent in terms of the thermoelectric conversion performance.

Particularly, the dispersing agents 1 and 3 having a structure in which X was an oxygen atom and Ra was an aromatic fused ring group in the repeating unit (1A) and Rb was derived from a poly(meth)acrylate compound in the repeating unit (1B) exhibited particularly excellent dispersibility and electrical conductivity.

### Example 2

A dispersion liquid 107 and a thermoelectric conversion element 107 were produced in the same manner as the dispersion liquid 101 and the thermoelectric conversion element 101, except that the dispersing agents shown in Table 2 were used instead of the dispersing agent 1, and the temporal change of the dispersibility, the electrical conductivity, and the thermoelectromotive force were evaluated.

Furthermore, the film strength of the thermoelectric conversion layer was evaluated using the following method.

[Film Strength]

A pencil hardness test was carried out on the formed thermoelectric conversion layer, and the film strength was evaluated using the following standards.

A: The test was carried out using a 4B pencil, and scratches on the film could not be visually observed.

B: The test was carried out using a 4B pencil, and scratches on the film could be visually observed.

TABLE 2

| Thermoelectric | | Temporal | Electrical | Thermoelectromotive | | |
|---|---|---|---|---|---|---|
| conversion | Dispersing | change of | conductivity | force S | Film | |
| element | agent | dispersibility | (S/cm) | (μV/K) | strength | Note |
| 107 | 7 | B | 300 | 28 | A | Present |
| | | | | | | Invention |

As is clear from Table 2, the thermoelectric conversion material manufactured using the dispersing agent 7 had favorable dispersibility, and the thermoelectric conversion element manufactured using the thermoelectric conversion material exhibited a high electrical conductivity and a high thermoelectromotive force and was excellent in terms of the thermoelectric conversion performance. Furthermore, the film strength of the thermoelectric conversion layer was excellent.

The invention has been explained together with the examples, but the present inventors do not intend to limit the invention in any detailed parts of the explanation unless particularly otherwise described and consider that the invention should be widely interpreted within the spirit and scope of the invention described in the accompanying claims.

### EXPLANATION OF REFERENCES

1, 2: Thermoelectric conversion element
11, 17: Metal plate
12, 22: First base material
13, 23: First electrode
14, 24: Thermoelectric conversion layer
15, 25: Second electrode
16, 26: Second base material

What is claimed is:

1. A thermoelectric conversion element comprising, on a base material:
a first electrode;
a thermoelectric conversion layer; and
a second electrode,
wherein a thermoelectric conversion layer is formed using a thermoelectric conversion material containing (a) a carbon nanotube and (b) a dispersing agent including a repeating unit represented by General Formula (1A) below and a repeating unit represented by General Formula (1B) below: 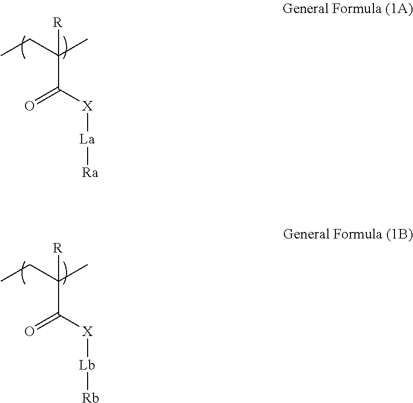
in General Formula (1A), Ra represents an aromatic group, an alicyclic group, an alkyl group, a hydroxyl group, a thiol group, an amino group, an ammonium group, or a carboxyl group; La represents a single bond or a divalent linking group; R represents a hydrogen atom or an alkyl group having 1 to 4 carbon atoms; and X represents an oxygen atom or —NH—, and
in General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; Lb represents a single bond or a divalent linking group; R is identical to that in General Formula (1A); and X represents an oxygen atom or —NH—.

2. The thermoelectric conversion element according to claim 1,
wherein, in General Formula (1A), X is —NH—.

3. The thermoelectric conversion element according to claim 1,
wherein, in General Formula (1A), X is —NH—, and Ra is an aromatic group.

4. The thermoelectric conversion element according to claim 1,
wherein, in General Formula (1A), X is an oxygen atom, and Ra is a hydroxyl group.

5. The thermoelectric conversion element according to claim 1,
wherein, in General Formula (1B), Rb is a monovalent group derived from a poly(meth)acrylate compound.

6. The thermoelectric conversion element according to claim 1, comprising:
a solvent.
